(19) United States
(12) Patent Application Publication
(10) Pub. No.: US 2004/0259385 A1
(43) Pub. Date: Dec. 23, 2004

(54) Method of forming insulating film improved in electric insulating property

(75) Inventors: Toshihide Takimoto, Chuo-ku (JP); Shuji Fujiwara, Kawasaki (JP); Tsuyoshi Setokubo, Higashihiroshima-shi (JP); Toshiyuki Hirota, Chuo-ku (JP); Fumiki Aiso, Chuo-ku (JP)

Correspondence Address: SUGHRUE MION, PLLC, 2100 PENNSYLVANIA AVENUE, N.W., SUITE 800, WASHINGTON, DC, 20037, US

(73) Assignees: ELPIDA MEMORY, INC.; NEC ELECTRONICS CORPORATION; NEC HIROSHIMA, Ltd.

(21) Appl. No.: 10/847,331

(22) Filed: May 18, 2004

(30) Foreign Application Priority Data
May 19, 2003 (JP) 2003-140667

(51) Int. Cl. H01L 21/31

(52) U.S. Cl. 438/791

(57) ABSTRACT

A method of forming an insulating film according to the present invention reacts a nitrogen containing gas with a compound composed of silicon and chlorine under the condition that the gas flow ratio of the compound to the nitrogen containing gas is lower than 1/30 to form a silicon nitride film. In the present invention, by forming the silicon nitride film at the gas flow ratio lower than 1/30, an insulating film having this silicon nitride film is improved in electric insulating property, so that a smaller leak current flows therethrough.

### BACKGROUND OF THE INVENTION

1. Field of the Invention

The present invention relates to a semiconductor device manufacturing process, and more particularly, to a method of forming an insulating film.

2. Description of the Related Art

For establishing a manufacturing process for next-generation semiconductor devices which entail design rules that are required to accomplish a minimum dimension of 0.14 μm or less, the diffusion of impurities must be further reduced within semiconductor substrates. For this purpose, a silicon nitride film, which is used to insulate conductors from one another, must be formed at lower temperatures. However, when a silicon nitride film is formed at temperatures decreased to as low as approximately 600° C. with conventionally used reaction gases, i.e., dichlorosilane (SiH₂Cl₂, hereinafter called the “DCS”) and ammonia (NH₃), the resulting silicon nitride film suffers from a suddenly reduced deposit rate and an insufficient throughput. To address these problems, the DCS has been replaced with hexachlorodisilane (Si₂Cl₆, hereinafter called the “HDC”) for forming a silicon nitride film because of its ability to deposit a film even at temperatures of approximately 600° C., as disclosed in Japanese Patent Laid-open Publication No. 343793/2002.

In the following, a silicon nitride film which is formed using DCS for a reaction gas is designated by DCS-Si₃N₄, while a silicon nitride film which is formed using HCD for a reaction gas is designated by HCD-Si₃N₄.

Now, DRAM (Dynamic Random Access Memory) will be described as an example of a semiconductor device which employs HCD-Si₃N₄.

FIG. 1 is a cross-sectional view illustrating an exemplary structure of a memory cell in DRAM. It should be noted that while Si (silicon) substrate 100, which is a semiconductor substrate, is formed with transistors each having a source electrode, a drain electrode, and the like, such transistors are omitted in the illustration because they are similar in structure to conventional ones.

As illustrated in FIG. 1, plugs 120a, 120b formed in interlayer insulating film 102 are connected to source electrodes (not shown) formed within Si substrate 100. Plug 122a connected to plug 120a, and plug 122b connected to plug 120b are formed in interlayer insulating film 104 and interlayer insulating film 106, respectively. Plugs 122a, 122b are connected to lower electrodes 124a, 124b, respectively, of capacitance cylinders formed within interlayer insulating film 108.

Plugs 120a, 120b, 122a, 122b are each formed by diffusing impurities into polysilicon embedded in openings within the interlayer insulating film. Thus, lower electrodes 124a, 124b are connected to source electrodes (not shown) to provide electric conduction therebetween. In the following description, a connection comprised of plugs 120a and 122a, and a connection comprised of plugs 120b and 122b are each called a “capacitive contact plug.”

Bit lines 110a, 110b, 110c are formed within interlayer insulating film 106. Each of bit lines 110a, 110b, 110c is formed of a tungsten nitride film and a tungsten film in order. Interlayer insulating films 102 to 108 are laminated in sequence, where each of interlayer insulating films 102-108 is made, for example, of silicon oxide film.

It should be noted that since components such as the dielectric, upper electrodes, and the like formed above lower electrodes 124a, 124b of the capacitance cylinders are similar in structure to before, these components are omitted in the illustration.

CAP nitride film 150 is formed on bit lines 110a, 110b, and spacer nitride film 160 is formed on side walls of bit lines 110a, 110b in order to electrically insulate capacitive contact plug 130a from bit lines 110a, 110b. Spacer nitride film 160 is formed of the aforementioned HCD-Si₃N₄. Spacer nitride film 160 for electrically insulating capacitive contact plug 130b from bit lines 110b, 110c is also formed of HCD-Si₃N₄.

Now, a method of forming spacer nitride film 160 will be described in brief. After bit line 110 and CAP nitride film 150 are laminated in order to form a laminate, HCD-Si₃N₄ is formed. Subsequently, HCD-Si₃N₄ is anisotropically etched to form spacer nitride film 160 on side walls of the laminate comprised of bit line 1 10 and CAP nitride film 150, as illustrated in FIG. 1.

Next, a method of forming HCD-Si₃N₄ will be described in detail.

HCD-Si₃N₄ is formed on the surface of a semiconductor substrate by supplying HCD and NH₃ at a gas flow ratio HCD/NH₃ equal to 1/30 (HCD gas flow rate:30 cc/min, NH₃ gas flow rate:900 cc/min) into a reaction tube, which has been decompressed by a CVD (Chemical Vapor Deposition) system, for reaction. In this event, HCD-Si₃N₄ exhibits a deposit rate which is equivalent to that exhibited by DCS-Si₃N₄ formed at 760° C., even if HCD-Si₃N₄ is formed at relatively low temperatures of approximately 600° C., lower than 700° C., from which it is appreciated that HCD-Si₃N₄ excels in productivity.

Conventionally, a single-wafer CVD system has been utilized to form a silicon nitride film on semiconductor substrates one by one in order to reduce the amount of heat treatment applied to semiconductor devices. Even in comparison with DCS-Si₃N₄ formed by the single-wafer CVD system, it has been confirmed that HCD-Si₃N₄ is advantageous in step coverage and pattern density dependence.

However, when HCD-Si₃N₄ formed by the foregoing method was used for a spacer nitride film for bit lines in DRAM, faults were found in a reliability test. An investigation on an estimated cause revealed that a leak current between a capacitive contact plug and a bit line was larger than when DCS-Si₃N₄ was used for the spacer nitride film. Accordingly, a leak current characteristic was confirmed for HCD-Si₃N₄, showing a leak current of approximately 3 E−4 [A/cm²] at an electric field strength of 4 [MV/cm], which is larger approximately by three orders of magnitude than a leak current value of DCS-Si₃N₄ which was 2 E−7 [A/cm²]. Thus, it was clarified that HCD-Si₃N₄ was inferior to DCS-Si₃N₄ in leak current characteristic.

### SUMMARY OF THE INVENTION

It is an object of the present invention to provide a method of forming an insulating film which excels more in the leak current characteristic than before.

The method of forming an insulating film according to the present invention reacts a nitrogen containing gas with a compound composed of silicon and chlorine under a condition that the gas flow ratio of the compound to the nitrogen containing gas is lower than 1/30 to form a silicon nitride film. In the present invention, by forming the silicon nitride film at the gas flow ratio lower than 1/30, an insulating film having this silicon nitride film is improved in electric insulating property, so that a smaller leak current flows therethrough.

In this event, when the gas flow ratio is chosen in a range of 1/100 to 1/150, the resulting silicon nitride film is further improved in insulating property, so that a further reduced leak current flows through an insulating film having this silicon nitride film.

Also, when the nitrogen containing gas is reacted with the compound at a temperature in a range of 400 to 700° C., a less amount of heat treatment is applied to semiconductor devices than before.

In conclusion, the method of forming an insulating film according to the present invention is capable of forming a high-quality silicon nitride film which has an improved film quality, and excels in leak current characteristic. Moreover, even at a processing temperature in a range of 400 to 700° C., the silicon nitride film can be formed at a throughput maintained sufficiently high, the semiconductor substrate is applied with a reduced amount of heat treatment. This can prevent the diffusion of impurities within the semiconductor substrate and increase the integration degree of the semiconductor device.

The above and other objects, features and advantages of the present invention will become apparent from the following description with reference to the accompanying drawings which illustrate examples of the present invention.

### BRIEF DESCRIPTION OF THE DRAWINGS

FIG. 1 is a cross-sectional view illustrating an exemplary structure of a memory cell in DRAM;

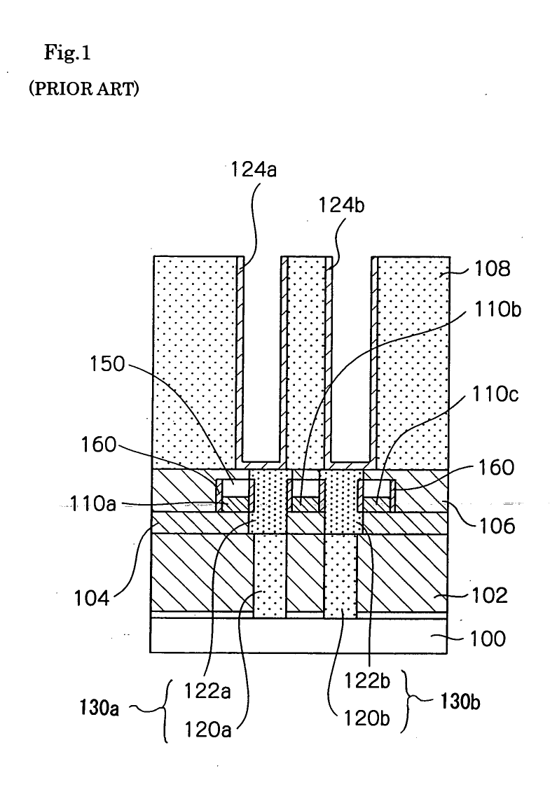

FIG. 2 is a block diagram illustrating an exemplary configuration of a vapor-phase growth system for forming a silicon nitride film; and

FIG. 3 is a graph showing the dependence on electric field strength of a leak current which flows through a silicon nitride film.

### DETAILED DESCRIPTION OF THE PREFERRED EMBODIMENTS

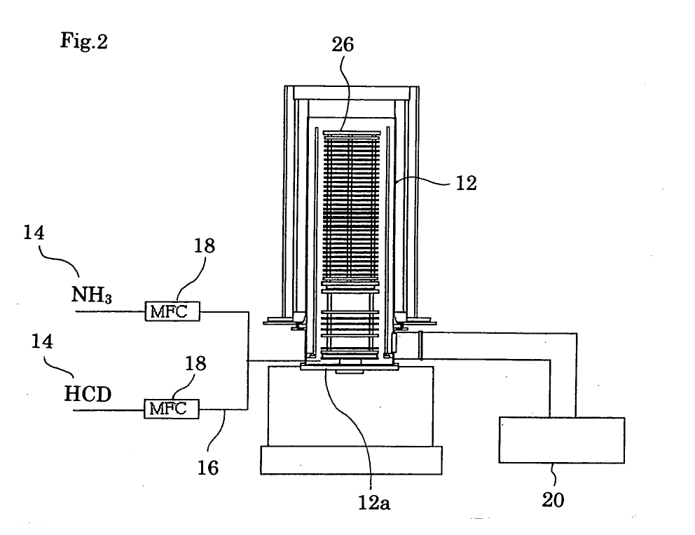

To begin with, description will be made on a vapor-phase growth system for use with a method of forming an insulating film according to the present invention. FIG. 2 is a block diagram illustrating an exemplary configuration of a vapor-phase growth system for forming a silicon nitride film. Assume in the following description that semiconductor substrates include not only a substrate made of Si and or the like but also a substrate such as a Si substrate which has been formed with semiconductor elements, interlayer insulating films, and the like.

The vapor phase growth system illustrated in FIG. 2 is a batch-type low pressure CVD system which is capable of forming silicon nitride films on a plurality of semiconductor substrates at one time. The illustrated vapor phase growth system comprises processing furnace 12 for forming a nitride film on a semiconductor substrate; gas conduits 16 for introducing reaction gases 14 into processing furnace 12 for forming the nitride film; mass flow controllers (MFC) 18 each for controlling the flow rate of associated reaction gas 14; vacuum pump 20 for exhausting gases in processing furnace 12; and a controller (not shown) for controlling the flow rates of various reaction gases, as well as the temperature and pressure within the processing furnace 12.

Processing furnace 12 comprises lid 12a for isolating the interior of processing furnace 12 from external air; a heater for uniformly maintaining the interior of processing furnace 12 at a predetermined temperature; a temperature sensor for monitoring the temperature within processing furnace 12; and a pressure sensor for monitoring the pressure within processing furnace 12. A transport robot is also provided for carrying wafer board 26, which is loaded with a plurality of semiconductor substrates, into processing chamber 12 and removing wafer board 26 from processing chamber 12. This transport robot comprises a position sensor for monitoring the presence or absence of a cassette, the position of wafer board 26, and the like. The transport robot carries unprocessed semiconductor substrates on wafer board 26 from a cassette yard, not shown, and returns processed semiconductor substrates from wafer board 26 to the cassette.

The controller comprises a CPU (Central Processing Unit) for executing predetermined processing in accordance with a program, and a memory for storing the program. The controller is connected to control signal lines for sending control signals to the heater, MFC 18, exhaust pump 20, and transport robot, and to monitor signal lines for receiving signals from a variety of sensors. The controller controls the respective components through the control signal lines and monitor signal lines, and executes processing in accordance with processing conditions previously registered by the operator to form a nitride film on each semiconductor substrate.

Next, description will be made on an experiment which was made for evaluating the quality of silicon nitride films which were formed under different conditions from before, including a different gas flow ratio HCD/NH₃.

TEG (Test Element Group) used in the experiment has two flat conductors in a predetermined pattern, and a silicon nitride film sandwiched between the two conductors for measuring a leak current through the silicon nitride film. Films were formed commonly under the same conditions except for the gas flow ratio HCD/HN₃. Respective samples were manufactured in the following procedure at four different gas flow ratios HCD/HN₃ of 1:50, 1:100, 1:120, and 1:150.

In the vapor phase growth system illustrated in FIG. 2, processing furnace 12 is heated by the heater to maintain the interior of processing furnace 12 at a predetermined temperature in a range of 400 to 700° C. Then, semiconductor substrates placed on wafer board 26 are carried into processing furnace 12. Next, lid 12a is closed to hermetically seal processing furnace 12 from which air is exhausted by a vacuum pump to decompress the interior of processing furnace 12 at a predetermined pressure in a range of 13.3 to 266 Pa (0.1 to 2.0 Torr). Subsequently, HCD and NH₃ are supplied to processing furnace 12 at a predetermined gas flow ratio, for example, 1/100 (HCD gas flow rate:15 cc/min, NH₃ gas flow rate:1,500 cc/min) to form a silicon nitride film on a semiconductor substrate. In this way, samples are fabricated. Likewise, respective samples were fabricated at each of different gas flow ratios in the foregoing procedure.

Next, description will be made on the result of the experiment showing the leak current characteristic exhibited by each of the fabricated samples. Specifically, a leak current was measured as flowing through the silicon nitride film of each sample, while the silicon nitride film was applied with a voltage to generate an electric field strength which was varied from 0 to −5 [MV/cm].

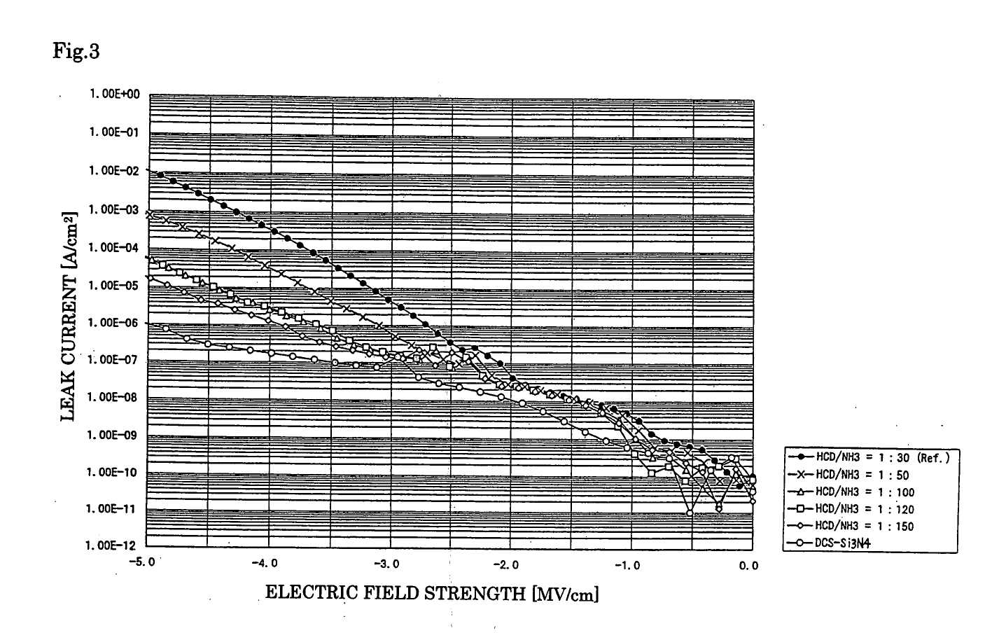

FIG. 3 is a graph showing the dependence on the electric field strength of the leak current flowing through the silicon nitride film, where the horizontal axis represents the electric field strength, and the vertical axis represents the leak current. It should be noted that the leak currents were evaluated in a range of −3 to −5 [MV/cm] of electric field strength because the leak currents were smaller than 1 E−7 [A/cm²] in a range of 0 to 3 [MV/cm] of electric field strength and were therefore more susceptible to noise.

As shown in FIG. 3, crosses, triangles, squares, and rhombuses were plotted to indicate leak currents associated with samples having the silicon nitride films formed at the gas flow ratios 1:50, 1:100, 1:120, and 1:150, respectively. For a comparison with the result of each sample, black circles are plotted to indicate a leak current associated with a conventional silicon nitride film formed at a gas flow ratio HCD/NH₃ of 1:30, and white circles are also plotted to indicate a leak current associated with conventional DCS-Si₃N₄. Any of the samples tends to have a leak current which increases as the absolute value of the electric field strength is larger.

The leak currents of the respective samples are compared with one another at the electric field strength of −4 [MV/cm]. The conventional silicon nitride film formed at the gas flow ratio HCD/NH₃ equal to 1:30 exhibits a leak current of approximately 3 E−4 [A/cm²]. As the gas flow. rate of ammonia is increased, the leak current decreases. Specifically, a sample fabricated at HCD/NH₃ equal to 1:100 exhibits a leak current reduced to approximately 2 E−6 [A/cm²], and a sample fabricated at HCD/NH₃ equal to 1:150 exhibits a leak current reduced to approximately 1 E−6 [A/cm²]. It can be seen from the graph of FIG. 3 that the leak current decreases as the gas flow rate of ammonia increases, to improve the film quality of the HCD-Si₃N₄.

The gas flow ratio HCD/NH₃ is more preferably in a range of 1/100 to 1/150 in which the leak current is reduced to approximately 2 E−6 [A/cm²] when the absolute value of the electric field strength is 4 [MV/cm].

In this embodiment, as the gas flow ratio HCD/NH₃ is chosen to be 1/30 or less for forming a silicon nitride film in the foregoing manner, the resulting silicon nitride film is improved in electric insulating property, causing a smaller leak current to flow through the silicon nitride film than before. Also, as the gas flow ratio HCD/NH₃ is chosen to be 1/100 or less, the resulting silicon nitride film is further improved in film quality, thus making it possible to form a high-quality silicon nitride film which further excels in leak current characteristic. Thus, an insulating film having the silicon nitride film according to this embodiment is improved in electric insulating property, and passes a smaller leak current therethrough than before.

Moreover, even at a processing temperature in a range of 400 to 700° C., the silicon nitride film can be formed at a throughput maintained sufficiently high, the semiconductor substrate is applied with a reduced amount of heat treatment. This can prevent the diffusion of impurities within the semiconductor substrate and increase the integration degree of the semiconductor device.

When a compound of silicon and chlorine is designated by SixCly, hexachlorodisilane used in the foregoing embodiment is represented by (x, y)=(2, 6). However, other values than (2, 6) may be employed for (x, y).

Also, while an ammonia gas is used for the formation of the silicon nitride film in the foregoing embodiment, any other gas may be used as long as it contains nitrogen.

While preferred embodiments of the present invention have been described using specific terms, such description is for illustrative purposes only, and it is to be understood that changes and variations may be made without departing from the spirit or scope of the following claims.

What is claimed is:

1. A method of forming an insulating film, comprising the steps of:
supplying a compound composed of silicon and chlorine, and a nitrogen containing gas under a condition that a gas flow ratio of said compound to said nitrogen containing gas is lower than 1/30; and
reacting said nitrogen containing gas with said compound to form a silicon nitride film.

2. The method of forming an insulating film according to claim 1, wherein said gas flow ratio is in a range of 1/100 to 1/150.

3. The method of forming an insulating film according to claim 1, wherein said nitrogen containing gas is reacted with said compound at a temperature in a range of 400 to 700° C.

4. The method of forming an insulating film according to claim 1, wherein said compound is hexachlorodisilane.

5. The method of forming an insulating film according to claim 1, wherein said nitrogen containing gas is ammonia.
